(19) United States
(12) Patent Application Publication
(10) Pub. No.: US 2021/0408228 A1
(43) Pub. Date: Dec. 30, 2021

(54) SEMICONDUCTOR DEVICE AND METHOD FOR FORMING SEMICONDUCTOR DEVICE

(71) Applicant: CHANGXIN MEMORY TECHNOLOGIES, INC., Hefei City (CN)

(72) Inventor: Xiguang LIU, Hefei (CN)

(73) Assignee: CHANGXIN MEMORY TECHNOLOGIES, INC., Hefei City (CN)

(21) Appl. No.: 17/446,083

(22) Filed: Aug. 26, 2021

Related U.S. Application Data
(63) Continuation of application No. PCT/CN2021/100514, filed on Jun. 17, 2021.

(30) Foreign Application Priority Data
Jun. 30, 2020 (CN) 202010610934.2

(51) Int. Cl. H01L 29/04; H01L 21/02

(52) U.S. Cl. CPC H01L 29/045; H01L 21/02271; H01L 21/02609; H01L 21/02433

(57) ABSTRACT

A method for forming a semiconductor device includes: a substrate is provided; a barrier layer is formed on an upper surface of the substrate, and a proportion of crystal orientation <111> in crystal orientations of the barrier layer is at least a preset value; and a metal material layer is formed on an upper surface of the barrier layer, crystal orientations of the metal material layer including a crystal orientation <111>.

### CROSS-REFERENCE TO RELATED APPLICATIONS

This is a continuation of International Application No. PCT/CN2021/100514 filed on Jun. 17, 2021, which claims priority to Chinese Patent Application No. 202010610934.2 filed on Jun. 30, 2020. The disclosures of these applications are hereby incorporated by reference in their entirety.

### BACKGROUND

With the continued reduction of device dimensions, aspect ratios of contact holes and through holes are continuously increased, which continuously challenges the process of chemical vapor deposition of metal tungsten. In integrated circuits, chemical vapor deposition of metal tungsten is commonly used for metal interconnections of contact windows or contact openings. With the continued reduction of device dimensions, aspect ratios of contact holes and through holes are continuously increased, which brings continuous challenges to the chemical vapor deposition process of metal tungsten.

### SUMMARY

The present disclosure relates generally to the field of semiconductor manufacture, and more specifically to a semiconductor device and a method for forming the semiconductor device.

A method for forming a semiconductor device is provided below. The method includes the following steps. A substrate is provided. A barrier layer is formed on an upper surface of the substrate, a proportion of crystal orientation <111> in crystal orientations of the barrier layer is at least a preset value. A metal material layer is formed on an upper surface of the barrier layer, crystal orientations of the metal material layer includes crystal orientation <111>.

A semiconductor device is also provided below. The semiconductor device includes: a substrate, an hole being formed in a surface of the substrate; a barrier layer formed on a bottom surface and a side wall surface of the hole, and an upper surface of the substrate, a proportion of crystal orientation <111> in crystal orientations of the barrier layer being at least a preset value; and a metal material layer formed on an upper surface of the barrier layer, crystal orientations of the metal material layer including crystal orientation <111>.

### BRIEF DESCRIPTION OF THE DRAWINGS

In order to describe the technical solutions in the examples of the present disclosure more clearly, the following briefly introduces the accompanying drawings required to be used in the examples of the present disclosure. It is apparent to those of ordinary skill in the art that the drawings in the following description are only some examples of the present disclosure, and that other drawings may be obtained from these drawings without involving any inventive effort.

FIG. 1 is a flow chart illustrating steps of a method for forming a semiconductor device in an example of the present disclosure.

FIG. 2A is a first structural diagram corresponding to a step of a method for forming a semiconductor device in an example of the present disclosure.

FIG. 2B is a second structural diagram corresponding to a step of a method for forming a semiconductor device in an example of the present disclosure.

FIG. 2C is a third structural diagram corresponding to a step of a method for forming a semiconductor device in an example of the present disclosure.

FIG. 2D is a fourth structural diagram corresponding to a step of a method for forming a semiconductor device in an example of the present disclosure.

FIG. 2E is a fifth structural diagram corresponding to a step of a method for forming a semiconductor device in an example of the present disclosure.

FIG. 2F is a sixth structural diagram corresponding to a step of a method for forming a semiconductor device in an example of the present disclosure.

FIG. 3 is a structural diagram of a semiconductor device in an example of the present disclosure.

### DETAILED DESCRIPTION

When metal tungsten is deposited by chemical vapor deposition, the following problems usually occur. Metal tungsten hangs over contact windows or contact openings to form an overhang. Voids will be formed in the metal tungsten layer deposited in the contact windows or the contact openings, thereby affecting the product yield.

That is, due to the insufficient ability of filling holes of metal tungsten during the chemical vapor deposition of metal tungsten, the problem of voids is easily caused.

In order to clarify the purpose, technical means, and effects of the present disclosure, the present disclosure will be further described below with reference to the accompanying drawings. It should be understood that the examples described herein are only a portion of the examples of the present disclosure, not all examples, and are not intended to limit the present disclosure. Based on the examples in the present disclosure, all other examples obtained by those skilled in the art without involving any inventive effort are within the scope of protection of the present disclosure.

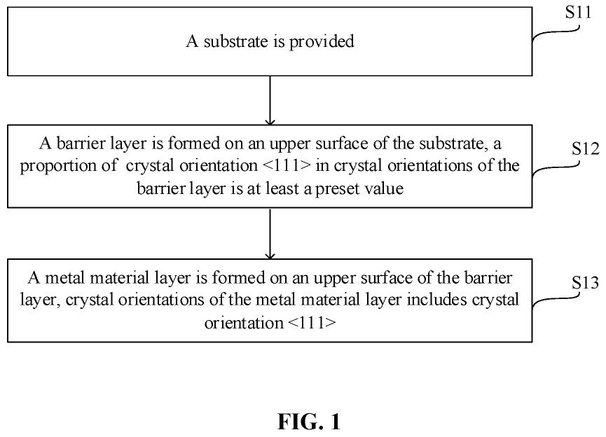

FIG. 1 shows a flow chart illustrating steps of a method for forming a semiconductor device in an example of the present disclosure. In this example, a method for forming a semiconductor device is proposed.

The method includes the following steps. At S11, a substrate is provided. At S12, a barrier layer is formed on an upper surface of the substrate. A proportion of crystal orientation <111> in crystal orientations of the barrier layer is at least a preset value. At S13, a metal material layer is formed on an upper surface of the barrier layer. Crystal orientations of the metal material layer include crystal orientation <111>.

According to the method for forming in this example, the barrier layer having the at least preset proportion of crystal orientation <111> is formed on the upper surface of the substrate, and it can be ensured that the metal material layer grown over the barrier layer mostly has the crystal orientation <111> by a proper preset value. The crystal plane of crystal orientation <111> is large, metal materials can be uniformly grown on all surfaces, when the method is used for filling the metal materials in holes, the possibility that voids are formed in the metal materials filled in the holes can be greatly reduced, and the production yield of the semiconductor device is improved.

In an example, the preset value is at least 70%. In an example, the preset value is preferably equal to or more than 90% or even 95%.

Since some of reactants have a corrosive effect on the substrate 101 during chemical vapor deposition, the barrier layer 103 can block the erosion of the substrate 101 by the reactants during deposition. In addition, the provision of a suitable barrier layer 103 may also be used to increase the adhesion between the metal material layer 102 and the substrate 101, thereby reducing the probability that the metal material layer 102 peels away from the surface of the substrate 101.

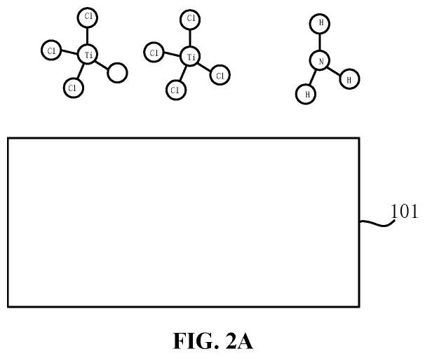

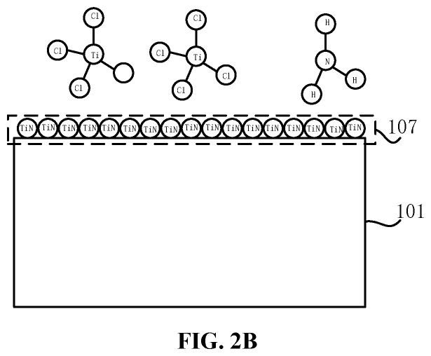

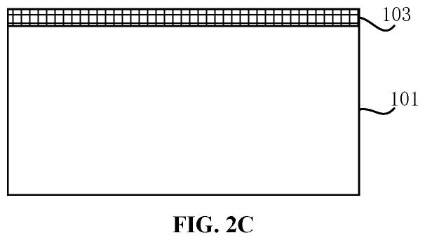

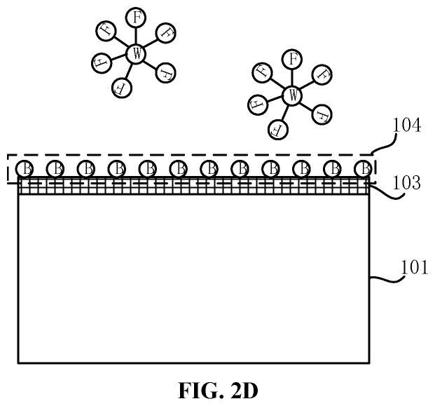

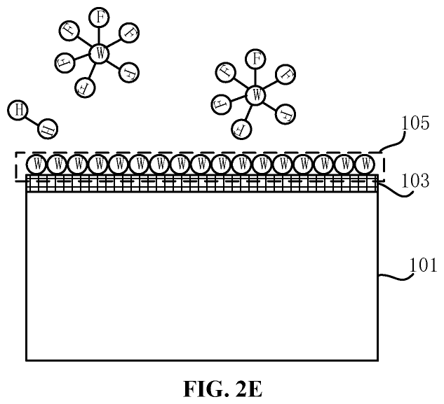

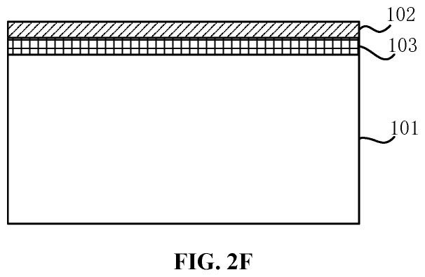

In an example, the operation of forming the barrier layer 103 on the upper surface of the substrate 101 includes the following steps. A crystal seed layer 107 having crystal orientation <111> is formed on the upper surface of the substrate 101, referring to FIGS. 2A and 2B herein. The barrier layer 103 having crystal orientation <111> is formed on the upper surface of the substrate 101 based on the crystal seed layer 107, referring to FIG. 2C herein.

In this example, the crystal seed layer 107 and the barrier layer 103 are sequentially formed by a chemical vapor deposition method. Forming the crystal seed layer 107 of a specific crystal orientation can be achieved by the flow quantity and flow velocity of the reaction gas during the chemical vapor deposition. In practice, atomic layer deposition, supercritical fluid deposition, metal organic chemical vapor deposition, chemical vapor deposition, and other methods may also be used to form the barrier layer 103 having crystal orientation <111>. When these methods are used to form the barrier layer 103 having crystal orientation <111>, a crystal seed layer 107 having the crystal orientation <111> is firstly formed on the upper surface of the substrate 101, and then the barrier layer 103 is formed based on the crystal seed layer 107 having crystal orientation <111>.

In an example, a reaction gas having a first partial pressure ratio is introduced over the substrate 101 to form the crystal seed layer 107, and the reaction gas having a second partial pressure ratio is introduced over the substrate to form the barrier layer 103. In an example, the reaction gas includes TiCl₄, NH₃, and a carrier gas including N₂, and the partial pressure of TiCl₄ in the first partial pressure ratio is smaller than that of TiCl₄ in the second partial pressure ratio.

By controlling the partial pressure of TiCl₄ in the first partial pressure ratio to be less than that of TiCl₄ in the second partial pressure ratio, the crystal orientation of crystal nuclei of TiN formed on the surface of the substrate 101 can be controlled substantially with crystal orientation <111>. In an example, the partial pressure of TiCl₄ in the firstly introduced reaction gases should be less than 10 mtorr, and the partial pressure of TiCl₄ in the next introduced reaction gases should be greater than or equal to 10 mtorr.

In other examples, the partial pressure of TiCl₄ in the first group of reaction gases and the second group of reaction gases can also be regulated by controlling the flows of NH₃ and N₂, etc.

In an example, the metal material layer 102 includes a tungsten layer. The operation of forming the metal material layer 102 on the upper surface of the barrier layer 103 includes the following steps. A reaction ion layer 104 is formed on the upper surface of the barrier layer 103, referring to FIG. 2D herein. A tungsten-containing gas is introduced over the reaction ion layer 104. The tungsten-containing gas reacts with the reaction ion layer 104 to form a tungsten crystal nucleus layer 105 on the surface of the barrier layer 103, referring to FIG. 2E herein. The tungsten-containing gas and a carrier gas are introduced over the tungsten crystal nucleus layer 105 to form the metal material layer 102, referring to FIG. 2F herein.

In this example, the reaction ion layer 104 is used for performing a displacement reaction with a subsequently introduced tungsten-containing gas to displace tungsten from the tungsten-containing gas to form a tungsten crystal nucleus layer 105 on the surface of the barrier layer 103. In this example, since the barrier layer 103 is a TiN layer having crystal orientation <111>, B₂H₆ may be selected as a preparation gas for the reaction ion layer 104. B₂H₆ has lower activation energy on the surface of the TiN layer having crystal orientation <111>. Thermodynamic auto-decomposition can be performed on the surface of the TiN layer to form more B ions.

In this example, the more B ions on the surface of the barrier layer 103, the easier it is to react with the tungsten-containing gas to form a tungsten crystal nucleus layer 105 with better step coverage, thereby improving tungsten coverage during the chemical vapor deposition.

In an example, the tungsten-containing gas includes tungsten hexafluoride. In practice, other tungsten-containing gases may be selected as desired to provide the desired tungsten ions for replacement.

In practical use, the barrier layer 103 not only has Tin with crystal orientation <111>, but also has TiN with other crystal orientations, but the hardness of a TiN film with crystal orientation <111> is relatively larger.

Therefore, in this example, by controlling a crystal structure of the barrier layer 103, nucleation of the tungsten crystal nucleus layer 105 can be promoted, and the ability of filling holes of tungsten can be improved during subsequent chemical vapor deposition.

In this example, the reaction ion layer 104 is a boron ion layer. The operation of forming the boron ion layer on the upper surface of the barrier layer 103 includes the step that a boron-containing gas is introduced over the barrier layer to form the boron ion layer.

In an example, the boron-containing gas includes B₂H₆. The B₂H₆ gas is decomposed on the surface of the barrier layer 103 to form the boron ion layer.

In an example, during the formation of crystal seed layer 107 and the barrier layer 103, TiCl₄ and NH₃ are introduced in different periods of time, and the remaining gas is blown out by N₂ after each introduction of TiCl₄ and NH₃. In practice, it is also possible to prepare the crystal seed layer 107 and the barrier layer 103 without using TiCl₄ and NH₃, but using a mixture of other gases such as TiCl₄, N₂, and Hz.

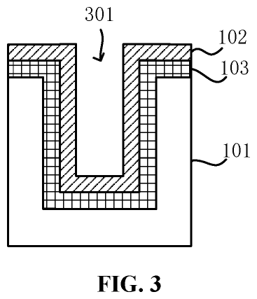

Referring to FIG. 3, in this example, a semiconductor device is also provided. The semiconductor device includes a substrate 101, a barrier layer 103, and a metal material layer 102. A hole 301 is formed in a surface of the substrate 101. The barrier layer is formed on a bottom surface and a side wall surface of the hole, and an upper surface of the substrate 101. A proportion of crystal orientation <111> in crystal orientations of the barrier layer is at least a preset value. The metal material layer is formed on an upper surface of the barrier layer 103. Crystal orientations of the metal material layer 102 include crystal orientation <111>.

According to the semiconductor device in this example, the barrier layer having the at least preset proportion of crystal orientation <111> is formed. Therefore, it can be ensured with the proper preset value that the metal material layer grown over the barrier layer mostly has crystal orientation <111>. The crystal plane of crystal orientation <111> is large, metal materials can be uniformly grown on all surfaces, when the method is used for filling the metal materials in holes, the possibility that voids are formed in the metal materials filled in the holes can be greatly reduced, and the production yield of the semiconductor device is improved.

In an example, the substrate 101 includes a silicon dioxide substrate. In practice, other types of substrates 101 may be provided as desired, such as a silicon-on-insulator substrate or a germanium-on-insulator substrate.

In an example, the metal material layer 102 can be formed over the substrate 101 by using atomic layer deposition. When the metal material layer 102 is deposited by using atomic layer deposition, the metal material layer has good step coverage and is used as a metal interconnection filling layer in the manufacturing process of the semiconductor device.

In an example, since some of reactants have a corrosive effect on the substrate 101 during chemical vapor deposition, the barrier layer 103 can also block the erosion of the substrate 101 by the reactants during deposition. In addition, the provision of a suitable barrier layer 103 may also be used to reduce the probability that the metal material layer 102 peels away from the surface of the substrate 101. With the crystal grains in the barrier layer having at least the preset proportion of crystal orientation <111>, the metal material layer formed on the barrier layer is β crystal phase with crystal orientation <111>, therefore rapid crystallization can be realized, the crystallization speed can be increased, and a uniform seed layer can be formed. The metal material layer having crystal orientation <111> is selected due to the large crystal plane of crystal orientation <111>, thus the metal material can be uniformly grown on each surface.

In an example, during the preparation of the metal material layer 102, the substrate 101 is firstly wet with B₂H₆ for a longer period of time so that the B₂H₆ can be decomposed on the surface of the substrate 101 and the formed B ions can stay on the surface of the substrate 101 as much as possible to form a B ion layer. In an example, the B ion layer has a thickness of 0.1-5 nm. In order to form as much metal tungsten with the crystal orientation <111> as possible over the substrate 101, a barrier layer 103 is provided as the barrier layer 103 with crystal orientation <111> herein. In an example, the barrier layer 103 includes TiN with crystal orientation <111>.

In practice, the barrier layer 103 may also have TiN with other crystal orientations. However, in order to grow metal tungsten with crystal orientation <111> as much as possible, it is necessary to ensure that the content of TiN with crystal orientation <111> in the barrier layer 103 is at least 70% of the total amount of TiN in the barrier layer 103. In an example, the preset value is preferably equal to or more than 90% or even equal to or more than 95%.

In an example, the barrier layer 103 has a thickness of 2-20 nm. In practice, the thickness of the barrier layer 103 may be set as desired.

After wetting the substrate 101 with B₂H₆ for a longer period of time, it is also necessary to introduce a tungsten-containing gas, such as tungsten hexafluoride, to the substrate 101. Tungsten from the tungsten-containing gas is displaced by B ions on the surface of the substrate 101 to form a tungsten crystal nucleus layer 105 on the surface of the substrate 101. In an example, the tungsten crystal nucleus layer 105 has a thickness of 2-10 nm.

Thereafter, tungsten in the tungsten-containing gas is reduced with hydrogen gas. At this moment, a carrier gas and the tungsten-containing gas are simultaneously introduced into a reaction space, and the metal material layer 102 is continuously formed on the basis of tungsten crystal nuclei. In an example, the metal material layer 102 has a thickness of 20-100 nm. In this example, the tungsten-containing gas also includes tungsten hexafluoride, and the carrier gas includes at least one of nitrogen, hydrogen, argon, etc.

Since the content of TiN with crystal orientation <111> in the barrier layer 103 is at least 70% of the total amount of TiN in the barrier layer 103, most of tungsten metal grown on the upper surface of the barrier layer 103 also has crystal orientation <111>. Tungsten with crystal orientation <111> has a large crystal plane and may be uniformly grown on each surface.

In a further example, silane (SiH₄) can also be used to reduce tungsten hexafluoride to form the tungsten crystal nuclei.

Although the present disclosure has been disclosed in terms of preferred examples, it is not intended to limit the present disclosure. Any person skilled in the art, without departing from the spirit and scope of the present disclosure, may make possible variations and modifications to the technical solution of the present disclosure using the methods and techniques disclosed above. Therefore, any simple modifications, equivalent variations and modifications made on the above examples according to the technical essence of the present disclosure without departing from the content of the technical solution of the present disclosure fall within the scope of protection of the technical solution of the present disclosure.

What is claimed is:

1. A method for forming a semiconductor device, comprising:
providing a substrate;
forming a barrier layer on an upper surface of the substrate, a proportion of crystal orientation <111> in crystal orientations of the barrier layer being at least a preset value; and
forming a metal material layer on an upper surface of the barrier layer, crystal orientations of the metal material layer comprising crystal orientation <111>.

2. The method for forming according to claim 1, wherein said forming the barrier layer comprises the following steps of:
forming a crystal seed layer having crystal orientation <111> on the upper surface of the substrate; and
forming the barrier layer having crystal orientation <111> on the upper surface of the substrate based on the crystal seed layer.

3. The method for forming according to claim 2, wherein a reaction gas having a first partial pressure ratio is introduced over the substrate to form the crystal seed layer, and the reaction gas having a second partial pressure ratio is introduced over the substrate to form the barrier layer.

4. The method for forming according to claim 3, wherein the reaction gas comprises TiCl₄, NH₃, and a carrier gas comprising N₂, and a partial pressure of TiCl₄ in the first partial pressure ratio is smaller than that of TiCl₄ in the second partial pressure ratio.

5. The method for forming according to claim 1, wherein the metal material layer comprises a tungsten layer, and forming the metal material layer on the upper surface of the barrier layer comprises the following steps:
forming a reaction ion layer on the upper surface of the barrier layer;
introducing a tungsten-containing gas over the reaction ion layer, the tungsten-containing gas reacting with the reaction ion layer to form a tungsten crystal nucleus layer on the surface of the barrier layer; and
introducing the tungsten-containing gas and a carrier gas over the tungsten crystal nucleus layer to form the metal material layer.

6. The method for forming according to claim 5, wherein the reaction ion layer is a boron ion layer, and forming the boron ion layer on the upper surface of the barrier layer comprises the following step:
introducing a boron-containing gas over the barrier layer to form the boron ion layer.

7. The method for forming according to claim 6, wherein the tungsten-containing gas comprises tungsten hexafluoride, the boron-containing gas comprises B₂H₆, and the carrier gas comprises at least one of H₂, Ar and N₂.

8. The method for forming according to claim 2, wherein during the crystal seed layer and the barrier layer being formed, TiCl₄ and NH₃ are introduced in different periods of time, and remaining gas is blown out by N₂ after each introduction of TiCl₄ and NH₃.

9. The method for forming according to claim 1, wherein the preset value is at least 70%.

10. A semiconductor device, comprising:
a substrate, a hole formed in a surface of the substrate;
a barrier layer formed on a bottom surface and a side wall surface of the hole and an upper surface of the substrate, a proportion of crystal orientation <111> in crystal orientations of the barrier layer being at least a preset value; and
a metal material layer formed on an upper surface of the barrier layer, crystal orientations of the metal material layer comprising crystal orientation <111>.

11. The semiconductor device according to claim 10, wherein the preset value is at least 70%.
